(19) United States
(12) Patent Application Publication
(10) Pub. No.: US 2024/0423072 A1
(43) Pub. Date: Dec. 19, 2024

(54) DISPLAY APPARATUS

(71) Applicant: LG DISPLAY CO., LTD., Seoul (KR)

(72) Inventors: Howon CHOI, Paju-si (KR); Taehyeon KIM, Paju-si (KR)

(73) Assignee: LG DISPLAY CO., LTD., Seoul (KR)

(21) Appl. No.: 18/743,922

(22) Filed: Jun. 14, 2024

(30) Foreign Application Priority Data
Jun. 19, 2023 (KR) 10-2023-0078468

(51) Int. Cl. H10K 59/80; H10K 59/122; H10K 102/10

(52) U.S. Cl. CPC H10K 59/879; H10K 59/122; H10K 59/80518; H10K 59/878; H10K 2102/103

(57) ABSTRACT

A display apparatus includes a substrate including a plurality of subpixels; a pattern portion having a concave shape and disposed between adjacent subpixels of the plurality of the subpixels; and a reflective portion disposed on the pattern portion, wherein each of the plurality of the subpixels includes a light emitting layer disposed on the substrate; and a nano-lens portion including a plurality of nano-lenses, and disposed between the light emitting layer and the substrate and spaced apart from the reflective portion, thereby improving a light extraction efficiency of light emitted from the light emitting layer.

### CROSS-REFERENCE TO RELATED APPLICATION

This application claims the priority of Korean Patent Applications No. 10-2023-0078468 filed on Jun. 19, 2023, which is hereby incorporated by reference in its entirety.

### BACKGROUND

### Field of the Disclosure

The present disclosure relates to a display apparatus displaying images.

### Description of the Background

An organic light emitting display (OLED) apparatus has a high response speed and a low power consumption and self-emits light without requiring a separate light source unlike a liquid crystal display apparatus. Therefore, the organic light emitting display apparatus has no problem in a viewing angle. As a result, the organic light emitting display apparatus has received attention as a next-generation flat panel display apparatus.

Such a display apparatus displays an image through light emission of a light emitting element layer that includes a light emitting layer interposed between two electrodes.

Meanwhile, light extraction efficiency of the display apparatus may be reduced as some of light emitted from the light emitting element layer is not emitted to the outside due to a total reflection on the interface between the light emitting element layer and an electrode and/or between a substrate and an air layer outside the apparatus.

### SUMMARY

Accordingly, the present disclosure is directed to a display apparatus that substantially obviates one or more of problems due to limitations and disadvantages described above.

More specifically, the present disclosure is to provide a display apparatus having an improved light extraction efficiency of light emitted from light emitting layer.

In addition, the present disclosure is to provide a display apparatus having characteristic of an improved viewing angle of a plurality of subpixels.

The present disclosure is also to provide a display apparatus having a light extraction efficiency that can be further increased through light extraction from non-emission area.

The present disclosure is also to provide a display apparatus having a reduced overall power consumption by light extraction.

Further, the present disclosure is directed to providing an optical member and a display apparatus including the optical member that may minimize or reduce the occurrence of radial rainbow patterns and radial circular ring patterns due to diffraction patterns of reflected light caused by destructive interference and/or constructive interference of light by reflection of external light.

The problems to be solved by the examples of the present disclosure are not limited to those mentioned above, and other problems not mentioned will be apparent to one of ordinary skill in the art to which the technical spirits of the present disclosure belong from the following description.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display apparatus includes a substrate including a plurality of subpixels; a pattern portion having a concave shape and disposed between adjacent subpixels of the plurality of the subpixels; and a reflective portion disposed on the pattern portion, wherein each of the plurality of the subpixels includes a light emitting layer disposed on the substrate; and a nano-lens portion including a plurality of nano-lenses, and disposed between the light emitting layer and the substrate and spaced apart from the reflective portion.

In another aspect of the present disclosure, a display apparatus includes a plurality of subpixels including an emitting area and a non-emitting area surrounding the emitting area; a pattern portion disposed in the non-emitting area and surrounding a plurality of subpixels; a reflective portion disposed on the pattern portion and having a curved surface; and at least one optical path changing portion disposed in the emitting area and the non-emitting area.

The technical benefits of the present disclosure are not limited to the above-mentioned benefits, and other benefits, which are not mentioned above, may be clearly understood by those skilled in the art from the following descriptions.

### BRIEF DESCRIPTION OF THE DRAWINGS

The accompanying drawings, which are included to provide a further understanding of the disclosure and are incorporated in and constitute a part of the disclosure, illustrate various aspects of the disclosure and together with the description serve to explain the principle of the present disclosure.

In the drawings:

FIG. 1 is a schematic plan view of a display apparatus according to one aspect of the present disclosure;

FIG. 2 is a schematic plan view of one pixel illustrated in FIG. 1;

FIG. 3 is a schematic cross-sectional view taken along line I-I′ illustrated in FIG. 2;

FIG. 4 is a schematic magnified view of portion A illustrated in FIG. 3;

FIG. 5 is a schematic magnified view of portion B illustrated in FIG. 4.

FIG. 6 is a schematic cross-sectional view taken along line II-II′ illustrated in FIG. 2;

FIG. 7 is a schematic cross-sectional view of a display apparatus according to a second aspect of the present disclosure; and

FIG. 8 is a schematic cross-sectional view of a display apparatus according to a third aspect of the present disclosure.

### DETAILED DESCRIPTION

Reference will now be made in detail to the aspects of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete, and will fully convey the scope of the present disclosure to those skilled in the art.

A shape, a size, a ratio, an angle, and a number disclosed in the drawings for describing aspects of the present disclosure are merely an example, and thus, the present disclosure is not limited to the illustrated details.

Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present specification are used, another part may be added unless ‘only-’ is used. The terms of a singular form may include plural forms unless referred to the contrary.

In construing an element, the element is construed as including an error range although there is no explicit description.

In describing a position relationship, for example, when a position relation between two parts is described as ‘on-’, ‘over-’, ‘under-’, and ‘next-’, one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction”, “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various aspects of the present disclosure may be partially or overall coupled to or combined with each other and may be variously inter-operated with each other and driven technically as those skilled in the art may sufficiently understand. The aspects of the present disclosure may be carried out independently from each other or may be carried out together in co-dependent relationship.

Hereinafter, various aspects of the present disclosure will be described in detail with reference to the accompanying drawings.

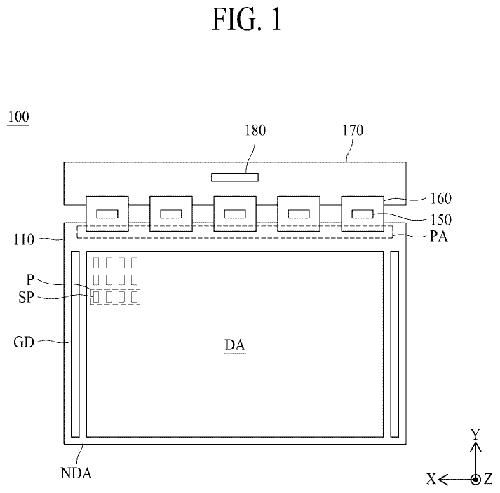

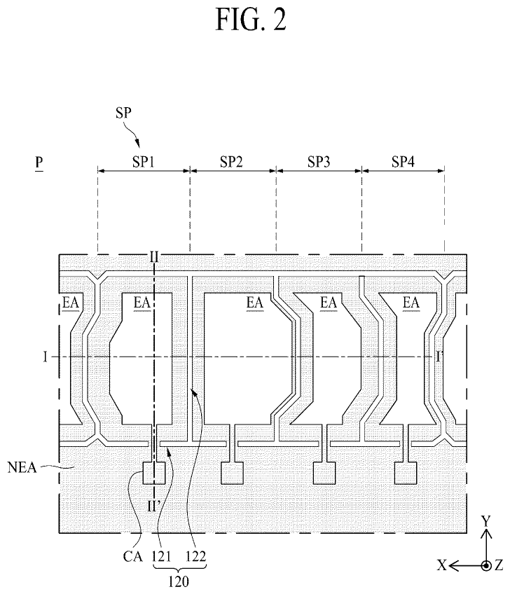

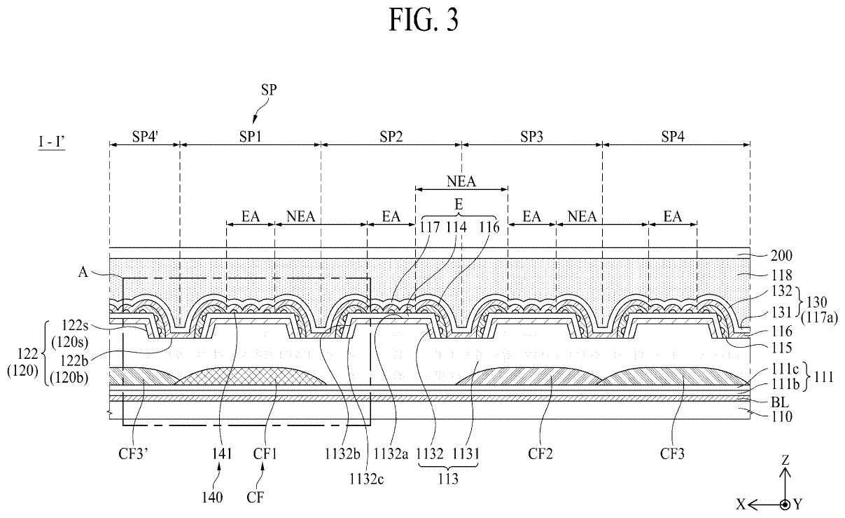

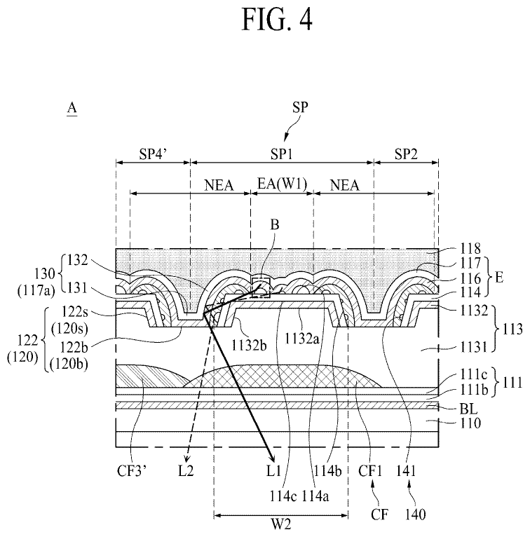

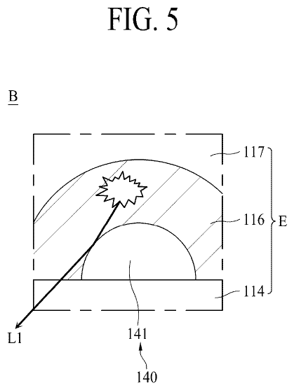

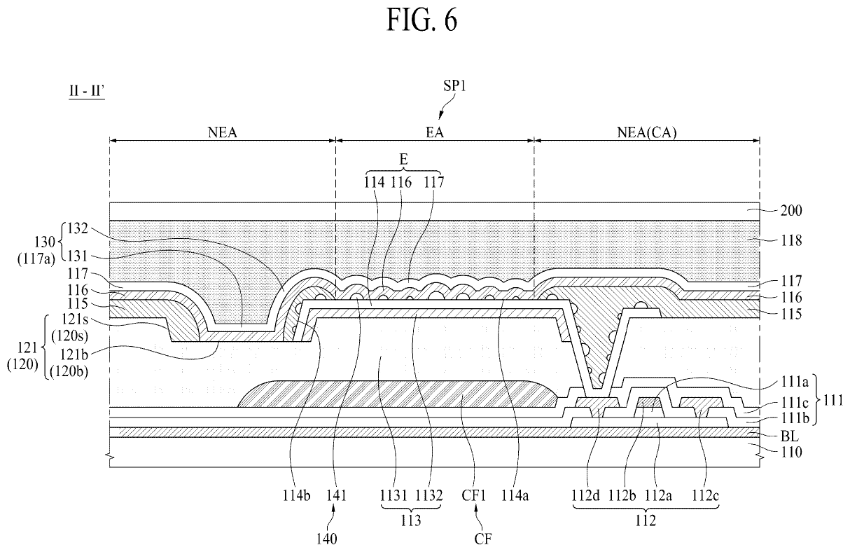

FIG. 1 is a schematic plan view of a display apparatus according to the one aspect of the present disclosure. FIG. 2 is a schematic plan view of one pixel illustrated in FIG. 1. FIG. 3 is a schematic cross-sectional view taken along line I-I′ illustrated in FIG. 2. FIG. 4 is a schematic magnified view of a portion A illustrated in FIG. 3. FIG. 5 is a schematic magnified view of a portion B illustrated in FIG. 4. FIG. 6 is a schematic cross-sectional view taken along line II-II′ illustrated in FIG. 2.

Referring to FIGS. 1 to 6, a display apparatus 100 according to one aspect of the present disclosure includes a substrate 110 having a plurality of pixels P having a plurality of subpixels SP, a pattern portion 120 disposed on the substrate 110 and formed to be concave between the plurality of subpixels SP, a reflective portion 130 on the pattern portion 120. Each of a plurality of subpixels SP according to one example may include a light emitting layer 116 disposed on the substrate 110 and a nano-lens portion 140 (or optical path changing portion) disposed between the light emitting layer 116 and the substrate 110. The nano-lens portion 140 includes a plurality of nano-lenses 141.

In the display apparatus 100 according to one exemplary aspect of the present disclosure, the nano-lens portion 140 may be disposed apart from the reflective portion 130. The nano-lens portion 140 according to one exemplary aspect may reflect or transmit light. Each of the plurality of nano-lenses 141 according to one exemplary aspect, may be formed in various shapes such as lens shape, hemisphere shape, uneven shape and the like. Accordingly, a portion of light emitted from the light emitting layer 116 may have its optical path changed to the reflective portion 130 by being reflected and/or refracted by the nano-lens portion 140. In addition, another portion of light emitted from the light emitting layer 116 may be reflected by the reflective portion 130 and then reflected and/or refracted by the nano-lens portion 140 (or optical path changing portion), thereby changing the optical path (or the path of the light). As described above, light emitted from the light emitting layer 116 may have its optical path changed by the reflective portion 130 and the nano-lens portion 140 disposed apart from the reflective portion 130.

Therefore, in the display apparatus 100 according to one aspect of the present disclosure, since each of the plurality of subpixels include the nano-lens portion 140 disposed apart from the reflective portion 130, the optical path may be changed by the reflective portion 130 and the nano-lens portion 140. Consequently, the display apparatus 100 according to one aspect of the present disclosure may improve light extraction efficiency of light emitted from the light emitting layer 116 because total reflection in the interface between the substrate 110 and an air layer may be reduced and a light that is extinguished due to the total reflection may be extracted to the outside of the substrate 110.

Meanwhile, the light whose optical path changed by the nano-lens portion 140 may be extracted (or emitted) through the light emission area EA, or the non-light emission (or non-emission) area NEA. The plurality of subpixels SP according to one exemplary aspect may include the light emission area EA and non-light emission (or non-emission) area NEA adjacent to the light emission area EA. The light emission area EA may be an area in which light is emitted and may be included in the display area DA. The non-light emission (or non-emission) area NEA may be an area in which light is not emitted, and an area adjacent to the light emission area EA. The non-light emission (or non-emission) area NEA may be expressed in terms of a peripheral area. In the display apparatus 100 according to one aspect of the present disclosure, the light emitted to the light emission area EA due to its optical path being changed by the nano-lens portion 140 may be defined to a first extraction light L1, and the light emitted to the non-light emission (or non-emission) area NEA due to its optical path being changed by the nano-lens portion 140 may be defined to a second extraction light L2.

For example, as shown in FIG. 4, a portion of light emitted from the light emitting layer 116 may be reflected firstly by one of the plurality of the nano-lenses 141, and the optical path of the light may be changed to the reflective portion 130. Next, after the light having the optical path toward the reflective portion 130 is reflected secondarily by the reflective portion 130, the light may not be totally reflected at the interface between the substrate 110 and the air layer and may be emitted to the light emission area EA. The above light may be the first extraction light L1.

Additionally, as shown in FIG. 4, another portion of light emitted from the light emitting layer 116 may be reflected firstly by one of the plurality of the nano-lenses 141, the optical path of the light may be changed to the reflective portion 130. Next, after the light having the optical path toward the reflective portion 130 is reflected secondarily by the reflective portion 130, the light may be reflected thirdly by the nano-lens 141 disposed on the side surfaces 114b of the pixel electrode 114. The light reflected thirdly may not be totally reflected at the interface between the substrate 110 and the air layer and be emitted to the non-light emission (or non-emission) area NEA. The above light may be the second extraction light L2.

In FIG. 4, only the first extraction light L1 and the second extraction light L2 are shown for convenience of explanation, but light emitted from the light emitting layer 116 may be in the form of direct light which is emitted directly to a lower surface of the substrate 110 without passing through the nano-lens portion 140 (or optical path changing portion) and the reflective portion 130.

The display apparatus according to the present disclosure includes the reflective portion 130 and the nano-lens portion 140 adjacent to the non-light emission (or non-emission) area NEA, so that the second extraction light L2 is emitted even from the non-light emission (or non-emission) area NEA, thereby improving the overall efficiency of the light extraction.

In addition, the display apparatus 100 according to one aspect of the present disclosure, as shown in FIG. 4, light may be scattered (or reflected and/or refracted) by the nano-lens portion 140 including the plurality of the nano-lenses 141, and thus the second extraction light L2 may be emitted towards the non-light emission (or non-emission) area NEA. Therefore, the display apparatus 100 according to one aspect of the present disclosure may have characteristic of the viewing angle improved compared to the display apparatus without the nano-lens portion 140.

Hereafter, a pattern portion 120, the reflective portion 130, and the nano-lens portion 140 included in the display apparatus 100 according to one aspect of the present disclosure are described in detail.

Since the display apparatus 100 according to one aspect of the present disclosure includes the reflective portion 130 and the nano-lens portion 140 in periphery of the non-light emission (or non-emission) area NEA, light directed to the adjacent subpixel SP among light emitted from the light emission area EA may be reflected toward the light emission area EA of the subpixel SP that emits light. Therefore, in the display apparatus 100 according to one aspect of the present disclosure, the light extraction efficiency of the subpixel SP that emits light may be improved. Here, the periphery of the non-light emission (or non-emission) area NEA may mean a partial area of the non-light emission (or non-emission) area NEA disposed apart from the light emission area EA or adjacent to the light emission area EA. For example, the peripheral of the non-light emission (or non-emission) area NEA may be the area surrounding the light emission area EA and disposed apart from the light emission area EA.

Since the display apparatus 100 according to one aspect of the present disclosure includes the nano-lens portion 140 peripheral to the light emission area EA and the non-light emission (or non-emission) area NEA, a portion of the light emitted from the light emitting layer 116 may be scattered. Therefore, the display apparatus 100 according to one aspect of the present disclosure may change the optical path from the non-light emission (or non-emission) area NEA to the light emission area EA through the nano-lens portion 140. Thus, the light extraction efficiency may be improved compared to the display apparatus without the nano-lens portion 140. In addition, since the display apparatus 100 according to one aspect of the present disclosure may change the optical path from the light emission area EA to the non-light emission (or non-emission) area NEA through the nano-lens portion 140, the characteristic of the viewing angle (or half luminance angle) may be improved compared to the display apparatus without the nano-lens portion 140.

The pattern portion 120 according to one example may be formed to be concave near the non-light emission (or non-emission) area NEA. For example, the pattern portion 120 may be formed to be concave in an overcoat layer 113 (shown in FIG. 3) on the substrate 110. As shown in FIG. 2, the pattern portion 120 may be provided to surround the light emission area EA. The pattern portion 120 may be disposed to be spaced apart from the light emission area EA. In FIG. 2, point hatching (or shading) is to indicate the bank. The pattern portion 120 according to one example may be provided to surround the light emission area EA in the form of a slit or a trench. For example, a width of the pattern portion 120 may be formed to be reduced from the reflective portion 130 toward the substrate 110. Also, as shown in FIG. 2, the pattern portion 120 may include an area exposed without being covered by the bank 115 (shown in FIG. 3). Therefore, the pattern portion 120 may be expressed as terms such as a groove, a slit, a trench, a bank slit and a bank trench.

The reflective portion 130 according to one example may be formed to be concave along a profile of the pattern portion 120 formed to be concave near the non-light emission (or non-emission) area NEA, thereby being formed to be concave near the non-light emission (or non-emission) area NEA. That is, the reflective portion 130 may be disposed along the peripheral area. The reflective portion 130 may be made of a material capable of reflecting light, and may reflect light, which is emitted from the light emission area EA and directed toward the adjacent subpixel SP, toward the light emission area EA of the subpixel SP for emitting light. Since the reflective portion 130 is disposed to be inclined while surrounding the light emission area EA, the reflective portion 130 may be expressed as terms such as a side reflective portion or an inclined reflective portion.

The reflective portion 130, as shown in FIG. 4, may include a flat surface 131 disposed on a center portion of a bank-less area which does not include a bank 115 and a curved surface 132 connected with the flat surface 131. The curved surface 132 of the reflective portion 130 may refer to the reflective portion 130 disposed in a portion of the bank area in which the bank 115 is disposed. The flat surface 131 may be disposed in parallel to the bottom surface 120b (shown in FIG. 4) of the pattern portion 120. The curved surface 132 may be formed in a rounded shape along a profile of the inclined surface 120s of the pattern portion 120. The light directed toward adjacent subpixel SP among light emitted from the subpixel SP emitting light may be mostly reflected by the curved surface 132 of the reflective portion 130 to be directed to the light emission area EA of the emitting subpixel SP or the non-light emission (or non-emission) area NEA of the emitting subpixel SP.

Meanwhile, the display apparatus 100 according to one aspect of the present disclosure may be implemented in a bottom emission type in which light emitted from the light emission area EA is emitted to the lower surface of the substrate 110. Therefore, in the display apparatus 100 according to one aspect of the present disclosure, the light emitted to the lower surface of the substrate 110 may be the light in which direct light emitted from the light emission area EA and directly emitted to the lower surface of the substrate 110 and an extraction light (or reflective light) obtained by reflecting the light, which is emitted from the light emission area EA and directed toward the adjacent subpixel SP, by the reflective portion 130 and/or the nano-lens portion 140 and emitting the light to the lower surface of the substrate 110 are combined with each other. Therefore, the display apparatus 100 according to one aspect of the present disclosure may more improve light extraction efficiency than the display apparatus in which the reflective portion 130 formed to be concave is not provided. In Addition, the display apparatus 100 according to one aspect of the present disclosure may have improved the light extraction efficiency and improved characteristic of the viewing angle compared to the display apparatus without the nano-lens portion 140 including the plurality of the nano-lenses 141.

The nano-lens portion 140 according to one exemplary aspect may be spaced apart from the reflective portion 130. The nano-lens portion 140 according to one exemplary aspect may reflect or transmit light. In one example, each of the plurality of the nano-lenses 141 included in the nano-lens portion 140 may include a more Indium (In) than the pixel electrode 114 comprising a transparent conductive material. In this case, since the nano-lenses 141 are close to a metal, the nano-lenses 141 may reflect light more than the pixel electrode 114. In another example, the plurality of the nano-lenses 141 may include similar indium (In) as the pixel electrode 114 or may include slightly more indium (In) than the pixel electrode 114. In this case, the nano-lenses 141 may be closer to a transparent conductive material than a metal, and thus the nano-lenses 141 may transmit some light and reflect some other light similar to the pixel electrode 114.

Each of the plurality of the nano-lenses 141 according to one exemplary aspect may be formed in various shapes such as lens shape, hemisphere shape, uneven shape and the like. Because each of the plurality of the nano-lenses 141 has a very small size, thus may be refer to in terms of a nano structure or a micro lens. In addition, since each of the plurality of the nano-lenses 141 has a very small size, thus may refer to in terms of roughness. The plurality of the nano-lenses 141 may be formed with uneven sizes, uneven shapes, and uneven intervals because the plurality of the nano-lenses 141 is formed by the plasma process using Hydrogen (H) or Ammonia (NH₃). For example, after the pixel electrode 114 comprising the transparent conductive material ITO is formed, the plasma process using Hydrogen (H) or Ammonia (NH₃) is performed, and thus the plurality of the nano-lenses 141 may be formed by precipitation of Indium(In) by radical reaction of Oxygen (O) and Hydrogen (H) in ITO according to the formula as follows.

3H₂+In₂O₃—3H₂O+2In

According to the chemical formula as described above, by the plasma process, Oxygen (O) contained in the pixel electrode 114 which is a transparent conductive material may be combined with Hydrogen (H) which is the plasma gas to generate water (H₂O), thereby being precipitated Indium(In). Therefore, the plurality of the nano-lenses 141 may include more Indium(In) than the pixel electrode 114. Therefore, the plurality of the nano-lenses 141 are closer to a metal than the pixel electrode 114, the light reflectance may be higher than the pixel electrode 114. Accordingly, as shown in FIG. 5, a portion of the light emitted from the light emitting layer 116 may be reflected by the nano-lens 141 including more Indium(In) than the pixel electrode 114, and thus its optical path may be changed to be emitted as the first extraction light L1 and/or the second extraction light L2.

As described above, since the plurality of the nano-lenses 141 are randomly and uneven formed on the upper surface 114a and the side surfaces 114b of the pixel electrode 114 by the plasma process using Hydrogen (H) or Ammonia (NH₃), the plurality of the nano-lenses 141 may have different sizes, shapes, and intervals thereof. Therefore, the amount of Indium(In) included in the plurality of the nano-lens 141 may be different, and thus some of the plurality of the nano-lenses 141 may include Indium (In) similar as the pixel electrode 114 or slightly more than the pixel electrode 114. In this case, the nano-lens 141 may have characteristic similar to the pixel-electrode 114, thus the nano-lens 141 may transmit a portion of the light and reflect another portion of the light.

Meanwhile, since some of the plurality of the nano-lens 141 may have characteristic similar to the pixel electrode 114 and the amount of the Indium thereof may be different, the pixel electrode 114 and the nano-lens 141 may have different refractive indices. Therefore, the light transmitting some of the nano-lenses 141 among the plurality of the nano-lenses 141 may be refracted by the interface between the nano-lens 141 and the pixel electrode 114, thus its optical path may be changed.

Accordingly, a portion of the light emitted from the light emitting layer 116 may be reflected and/or refracted by the nano-lens portion 140, thus its optical path may be changed to the reflective portion 130. In addition, another portion of the light emitted from the light emitting layer 116 may be reflected by the reflective portion 130 and then be reflected and/or refracted by the nano-lens portion 140, thus its optical path may be changed. As described above, the light emitted from the light emitting layer 116 may have its optical path changed by the reflective portion 130 and the nano-lens portion 140 spaced apart from the reflective portion 130.

Consequently, the display apparatus 100 according to one aspect of the present disclosure may improve the light extraction efficiency of the light emitted from light emitting layer 116 because the optical path of the light emitted from each of the plurality of the subpixels SP may be changed by the nano-lens portion 140 spaced apart from the reflective portion 130, thereby reducing the total reflection of the light at the interfere between the substrate 110 and the air layer.

Hereinafter, reference to FIGS. 1 to 4, the display apparatus 100 according to an aspect of the present specification will be described in more detail.

Referring to FIGS. 1 and 3, the display apparatus 100 according to one aspect of the present disclosure may further include a display panel including a gate driver (GD), the nano-lens portion 140, the source drive integrated circuit (hereinafter referred to as “IC”) 150, the flexible film 160, the circuit board 170, and the timing controller 180. The nano-lens portion 140 includes the plurality of the nano-lenses 141 and is disposed between the light emitting layer 116 and the substrate 110.

The display panel may include a substrate 110 and an opposite substrate 200 (shown in FIG. 3).

The substrate 110 may include a thin film transistor, and may be a transistor array substrate, a lower substrate, a base substrate, or a first substrate. The substrate 110 may be a transparent glass substrate or a transparent plastic substrate. The substrate 110 may include a display area DA and a non-display area NDA.

The display area DA is the area where an image is displayed. The display area DA may be a pixel array area, an active area, a pixel array unit, a display unit, or a screen. For example, the display area DA may be disposed in a central portion of the display panel. The display area DA may include a plurality of pixels P.

The opposite substrate 200 may encapsulate (or seal) the display area DA disposed on the substrate 110. For example, the opposite substrate 200 may be bonded to the substrate 110 via an adhesive member (or clear glue). The opposite substrate 200 may be an upper substrate, a second substrate, or an encapsulation substrate.

The gate driver GD supplies gate signals to the gate lines in accordance with the gate control signal input from the timing controller 180. The gate driver GD may be formed on one side of the light emission area EA or in the non-light emission (or non-emission) area NEA outside both sides of the light emission area EA in a gate driver in panel (GIP) method, as shown in FIG. 1.

The non-display area NDA is an area on which an image is not displayed, and may be a peripheral area, a signal supply area, an inactive area or a bezel area. The non-display area NDA may be configured to be in the vicinity of the display area DA. That is, the non-display area NDA may be disposed to surround the display area DA.

A pad area PA may be disposed in the non-display area NDA. The pad area PA may supply a power source and/or a signal for outputting an image to the pixel P provided in the display area DA. Referring to FIG. 1, the pad area PA may be provided above the display area DA.

The source drive IC 150 receives digital video data and a source control signal from the timing controller 180. The source drive IC 150 converts the digital video data into analog data voltages in accordance with the source control signal and supplies the analog data voltages to the data lines. When the source drive IC 150 is manufactured as a driving chip, the source drive IC 150 may be packaged in the flexible film 160 in a chip on film (COF) method or a chip on plastic (COP) method.

Pads, such as data pads, may be formed in the non-display area NDA of the display panel. Lines connecting the pads with the source drive IC 150 and lines connecting the pads with lines of the circuit board 170 may be formed in the flexible film 160. The flexible film 160 may be attached onto the pads by using an anisotropic conducting film, whereby the pads may be connected with the lines of the flexible film 160.

The circuit board 170 may be attached to the flexible films 160. A plurality of circuits implemented as driving chips may be packaged in the circuit board 170. For example, the timing controller 180 may be packaged in the circuit board 170. The circuit board 170 may be a printed circuit board or a flexible printed circuit board.

The timing controller 180 receives the digital video data and a timing signal from an external system board through a cable of the circuit board 170. The timing controller 180 generates a gate control signal for controlling an operation timing of the gate driver GD and a source control signal for controlling the source drive ICs 150 based on the timing signal. The timing controller 180 supplies the gate control signal to the gate driver GD, and supplies the source control signal to the source drive ICs 150.

Referring to FIGS. 2 and 3, the substrate 110 according to an example may include the light emission area EA and the non-light emission (or non-emission) area NEA.

The light emission area EA is the area where an image is displayed. The light emission area EA may be a pixel array area, an active area, a pixel array unit, a display unit, or a screen. For example, the light emission area EA may be disposed in a center portion of the display panel.

The light emission area EA according to an example may include gate lines, data lines, pixel driving power lines, and a plurality of pixels P. Each of the plurality of pixels P may include a plurality of subpixels SP that may be defined by the gate lines and the data lines.

Meanwhile, at least four subpixels, which are provided to emit different colors and disposed to be adjacent to one another, among the plurality of subpixels SP may constitute one pixel P (or unit pixel). One pixel P may include, but is not limited to, a red subpixel, a green subpixel, a blue subpixel and a white subpixel. One pixel P may include three subpixels SP provided to emit light of different colors and disposed to be adjacent to one another. For example, one pixel P may include a red subpixel, a green subpixel and a blue subpixel.

Each of the plurality of subpixels SP includes a thin film transistor and a light emitting element layer E connected to the thin film transistor. Each of the plurality of subpixels may include a light emitting layer (or an organic light emitting layer) interposed between the pixel electrode and the reflective electrode.

The light emitting layer respectively disposed in the plurality of subpixels SP may individually emit light of their respective colors different from one another or commonly emit white light. According to an example, when the light emitting layer of the plurality of subpixels SP commonly emit white light, each of the red subpixel, the green subpixel and the blue subpixel may include a color filter CF (or wavelength conversion member) for converting white light into light of its respective different color. In this case, the white subpixel according to an example may not include a color filter.

In the display apparatus 100 according to one aspect of the present disclosure, an area provided with a red color filter may be a red subpixel or a first subpixel, an area provided with a green color filter may be a green subpixel or a second subpixel, an area provided with a blue color filter may be a blue subpixel or a third subpixel, and an area in which the color filter is not provided may be a white subpixel or a fourth subpixel. However, the color corresponding to the subpixel is not limited thereto, the first subpixel may be a red subpixel, the second subpixel may be a white subpixel, the third subpixel may be a green subpixel, and the fourth subpixel may be a blue subpixel.

Each of the subpixels SP supplies a predetermined current to the organic light emitting element in accordance with a data voltage of the data line when a gate signal is input from the gate line by using the thin film transistor. For this reason, the light emitting layer of each of the subpixels may emit light with a predetermined brightness in accordance with the predetermined current.

The plurality of subpixels SP according to one example may be disposed to be adjacent to each other in a first direction (X-axis direction). The first direction (X-axis direction) may be a horizontal direction based on FIG. 2. The horizontal direction may be a direction in which a gate line GL is disposed.

A second direction (Y-axis direction) is a direction crossing the first direction (X-axis direction), and may be a vertical direction based on FIG. 2. The vertical direction may be a direction in which a data line is disposed.

A third direction (Z-axis direction) is a direction crossing each of the first direction (X-axis direction) and the second direction (Y-axis direction), and may be a thickness direction of the display apparatus 100.

The plurality of subpixels SP may include a first subpixel SP1, a second subpixel SP2, a third subpixel SP3 and a fourth subpixel SP4 arranged adjacent to each other in the first direction (X-axis direction). For example, the first subpixel SP1 may be a red subpixel, the second subpixel SP2 may be a green subpixel, the third subpixel SP3 may be a blue subpixel and the fourth subpixel SP4 may be a white subpixel, but is not limited thereto. However, the arrangement order of the first subpixel SP1, the second subpixel SP2, the third subpixel SP3 and the fourth subpixel SP4 may be changed.

Alternatively, as shown in FIG. 3, the second subpixel SP2 may be disposed adjacent to one side (or a right side) of the first subpixel SP1, the fourth subpixel SP4′ of another pixel P may be disposed adjacent to the other side (or a left side) of the first subpixel SP1.

Each of the first to fourth subpixels SP1 to SP4 may include a light emission area EA and a circuit area CA. The light emission area EA may be disposed at one side (or an upper side) of a subpixel area, and the circuit area CA may be disposed at the other side (or a lower side) of the subpixel area. For example, the circuit area CA may be disposed at the lower side of the light emission area EA based on the second direction Y. The light emission areas EA of the first to fourth subpixels SP1 to SP4 may have different sizes (or areas).

The first to fourth subpixels SP1 to SP4 may be disposed to be adjacent to one another along the first direction (X-axis direction). For example, two data lines extended along the second direction (Y-axis direction) may be disposed in parallel with each other between the first subpixel SP1 and the second subpixel SP2 and between the third subpixel SP3 and the fourth subpixel SP4. A pixel power line extended along the first direction (X-axis direction) may be disposed between the light emission area EA and the circuit area CA of each of the first to fourth subpixels SP1 to SP4. The gate line and a sensing line may be disposed below the circuit area CA. The pixel power line extended along the second direction (Y-axis direction) may be disposed at one side of the first subpixel SP1 or the fourth subpixel SP4. A reference line extended along the second direction (Y-axis direction) may be disposed between the second subpixel SP2 and the third subpixel SP3. The reference line may be used as a sensing line for sensing a change of characteristics of a driving thin film transistor and/or a change of characteristics of the light emitting element layer, which is disposed in the circuit area CA, from the outside in a sensing driving mode of the pixel P.

In the display apparatus 100 according to one aspect of the present disclosure, each of the plurality of the subpixels SP may include the nano-lens portion 140 having the plurality of the nano-lenses 141. The nano-lens portion 140 may partially overlap the light emission area EA of each of the subpixels SP. As shown in FIG. 4, the nano-lens portion 140 may be formed on the upper surface 114a of the pixel electrode 114 and the side surfaces 114b of the pixel electrode 114. The upper surface 114a of the pixel electrode 114 may be a surface facing the light emitting layer 116 or a surface contacting a lower surface of the light emitting layer 116. The plurality of the nano-lenses 141 included in the nano-lens portion 140 may be formed to have lens (or uneven) shapes on the upper surface 114a and the side surfaces 114b of the pixel electrode 114, thereby changing the optical path of the light emitted from the light emitting device layer E to increase the efficiency of the light extraction. For example, the nano-lens portion 140 may be a non-flat portion, an uneven pattern portion, a micro-lens portion, a light scattering pattern portion.

Meanwhile, in the display apparatus 100 according to one aspect of the present disclosure, since the pattern portion 120 is disposed to surround the light emission area EA, at least a portion of the reflective portion 130 on the pattern portion 120 may be disposed to surround the light emission area EA. Therefore, the reflective light may be emitted toward the substrate 110 from the position spaced apart from the light emission area EA while surrounding at least a portion of the light emission area EA.

Hereinafter, a structure of each of the plurality of subpixels SP will be described in detail.

Referring to FIG. 6, the display apparatus 100 according to one aspect of the present disclosure may further include a buffer layer BL, a circuit element layer 111, a thin film transistor 112, a pixel electrode 114, a bank 115, a light emitting layer 116, a reflective electrode 117, an encapsulation layer 118 and a color filter CF.

In more detail, each of the subpixels SP according to one aspect may include a circuit element layer 111 provided on an upper surface of a buffer layer BL, including a gate insulating layer 111a, an interlayer insulating layer 111b and a passivation layer 111c, an overcoat layer 113 provided on the circuit element layer 111, a pixel electrode 114 provided on the overcoat layer 113, a bank 115 covering an edge of the pixel electrode 114, a light emitting layer 116 on the pixel electrode 114 and the bank 115, a reflective electrode 117 on the light emitting layer 116, and an encapsulation layer 118 on the reflective electrode 117.

The thin film transistor 112 for driving the subpixel SP may be disposed on the circuit element layer 111. The circuit element layer 111 may be expressed as the term of an inorganic film layer. The pixel electrode 114, the light emitting layer 116 and the reflective electrode 117 may be included in the light emitting element layer E.

The buffer layer BL may be formed between the substrate 110 and the gate insulating layer 111a to protect the thin film transistor 112. The buffer layer BL may be disposed on the entire surface (or front surface) of the substrate 110. The buffer layer BL may serve to block diffusion of a material contained in the substrate 110 into a transistor layer during a high temperature process of a manufacturing process of the thin film transistor. Optionally, the buffer layer BL may be omitted in some cases.

The thin film transistor 112 (or a drive transistor) according to an example may include an active layer 112a, a gate electrode 112b, a source electrode 112c, and a drain electrode 112d.

The active layer 112a may include a channel area, a drain area and a source area, which are formed in a thin film transistor area of a circuit area of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As an example, the gate insulating layer 111a may be formed in an island shape only on the channel area of the active layer 112a, or may be formed on an entire front surface of the substrate 110 or the buffer layer BL, which includes the active layer 112a.

The gate electrode 112b may be formed on the gate insulating layer 111a to overlap the channel area of the active layer 112a.

The interlayer insulating layer 111b may be formed on the gate electrode 112b and the drain area and the source area of the active layer 112a. As in FIG. 5, the interlayer insulating layer 111b may be formed in the circuit area and an entire light emission area, in which light is emitted to the subpixel SP. However, aspects of the present disclosure are not limited thereto, the interlayer insulating layer 111b may be patterned between the drain electrode 112d and the gate electrode 112b and drain region of the active layer 112a and may be arranged in an island shape, and moreover, may be patterned between the source electrode 112c and the gate electrode 112b and source region of the active layer 112a and may be arranged in an island shape.

The source electrode 112c may be electrically connected to the source area of the active layer 112a through a source contact hole provided in the interlayer insulating layer 111b overlapped with the source area of the active layer 112a. The drain electrode 112d may be electrically connected to the drain area of the active layer 112a through a drain contact hole provided in the interlayer insulating layer 111b overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode.

In addition, the circuit area may further include first and second switching thin film transistors disposed together with the thin film transistor 112, and a capacitor. Since each of the first and second switching thin film transistors is provided on the circuit area of the subpixel SP to have the same structure as that of the thin film transistor 112, its description will be omitted. The capacitor (not shown) may be provided in an overlap area between the gate electrode 112b and the source electrode 112c of the thin film transistor 112, which overlap each other with the interlayer insulating layer 111b interposed therebetween.

Additionally, to prevent a threshold voltage of the thin film transistor provided in a pixel area from being shifted by light, the display panel or the substrate 110 may further include a light shielding layer (not shown) provided below the active layer 112a of at least one of the thin film transistor 112, the first switching thin film transistor or the second switching thin film transistor. The light shielding layer may be disposed between the substrate 110 and the active layer 112a to shield light incident on the active layer 112a through the substrate 110, thereby minimizing a change in the threshold voltage of the transistor due to external light. Also, since the light shielding layer is provided between the substrate 110 and the active layer 112a, the thin film transistor may be prevented from being seen by a user.

The passivation layer 111c may be provided on the substrate 110 to cover the pixel area. The passivation layer 111c covers a drain electrode 112d, a source electrode 112c and a gate electrode 112b of the thin film transistor 112, and the buffer layer BL. The passivation layer 111c may be formed over the circuit area and the light emission area. The passivation layer 111c may be omitted. The color filter CF may be disposed on the passivation layer 111c.

The overcoat layer 113 may be provided on the substrate 110 to cover the passivation layer 111c and the color filter CF. When the passivation layer 111c is omitted, the overcoat layer 113 may be provided on the substrate 110 to cover the circuit area. The overcoat layer 113 may be formed in the circuit area CA in which the thin film transistor 112 is disposed and the light emission area EA. In addition, the overcoat layer 113 may be formed in the other non-display area NDA except a pad area PA of the non-display area NDA and the entire display area DA. For example, the overcoat layer 113 may include an extension portion (or an enlarged portion) extended or enlarged from the display area DA to the other non-display area NDA except the pad area PA. Therefore, the overcoat layer 113 may have a size relatively wider than that of the display area DA.

The overcoat layer 113 according to one example may be formed to have a relatively thick thickness, thereby providing a flat surface on the display area DA and the non-display area NDA. For example, the overcoat layer 113 may be made of an organic material such as photo acryl, benzocyclobutene, polyimide and fluorine resin.

The overcoat layer 113 may be disposed between the passivation layer 111c and the pixel electrode 114 and include an upper surface 1132a and side surfaces 1132b. The overcoat layer 113 according to one exemplary aspect may include a first layer 1131 and a second layer 1132. The first layer 1131 is disposed between the passivation layer 111c and the pixel electrode 114. The second layer 1132 covers the first layer 1131 and has an end partially contacting the bottom surface 120b of the pattern portion 120. Alternatively, the overcoat layer 113 may include the first layer 1131 contacting the passivation layer 111c and the color filter CF, and the second layer 1132 disposed on the first layer 1131. As the second layer 1132 is disposed on the first layer 1131, the upper surface 1132a and the side surfaces 1132b of the overcoat layer 113 may be an upper surface and side surfaces of the second layer 1132.

The first layer 1131 according to one exemplary aspect may be formed as one body except for a contact hole of the pixel electrode 114 and a contact hole of the thin film transistor 112. On the other hand, the second layer 1132 according to one exemplary aspect as shown in FIG. 6, may be formed to overlap the entire light emission area EA and a portion of the non-light emission (or non-emission) area NEA. Thus, the second layer 1132 may be formed on the first layer 1131 by being patterned in an island shape. The first layer 1131 and the second layer 1132 may be formed to have the same refractive index, but refractive indices of the first layer 1131 and the second layer 1132 are not limited thereto, the first layer 1131 and the second layer 1132 may have different refractive indices. When the refractive indices of the first layer 1131 and the second layer 1132 are different (for example, the refractive index of the second layer 1132 is greater than the refractive index of the first layer 1131), the optical path of the light directed toward the adjacent subpixel SP among light emitted from the light emitting device layer E may be changed to the reflective portion 130 according to the refractive index difference between the first layer 1131 and the second layer 1132. Therefore, the display apparatus 100 according to one aspect of the present disclosure may reduce or prevent color mixing with adjacent subpixels SP.

As shown in FIG. 3, the second layer 1132 the display apparatus 100 according to one aspect of the present disclosure may include the upper surface 1132a, the side surfaces 1132b, and the end 1132c. The upper surface 1132a of the second layer 1132 may be flat, and the side surfaces 1132b of the second layer 1132 may be inclined.

Meanwhile, the pixel electrode 114 is formed on the upper surface 1132a of the second layer 1132 so that the pixel electrode 114 may be provided to be flat, and the light emitting layer 116 and the reflective electrode 117, which are formed on the pixel electrode 114, may be provided to be also flat. Since the pixel electrode 114, the light emitting layer 116, the reflective electrode 117, that is, the light emitting element layer E is provided to be flat in the light emission area EA, a thickness of each of the pixel electrode 114, the light emitting layer 116 and the reflective electrode 117 in the light emission area EA may be uniformly formed. Therefore, the light emitting layer 116 may be uniformly emitted without deviation in the light emission area EA.

Referring to FIG. 3, the color filter CF disposed in the light emission area EA may be provided between the substrate 110 and the overcoat layer 113. The color filter CF may include a red color filter (or a first color filter) CF1 for converting white light emitted from the light emitting layer 116 into red light, a green color filter (or a second color filter) CF2 for converting white light into green light, and a blue color filter (or a third color filter) CF3 for converting white light into blue light. The fourth subpixel, which is a white subpixel, may not include a color filter since the light emitting layer 116 emits white light. That is, in the display apparatus 100 according to one aspect of the present disclosure, the color filter CF may be disposed in only some of the plurality of the subpixels SP. Alternatively, as shown in FIG. 3, the fourth subpixel SP4′ of another subpixel P may be disposed adjacent to the other side (or a left side) of the first subpixel SP1, the blue color filter (or the third color filter) CF3′ may be disposed in the fourth subpixel SP4.

As shown in FIG. 3, the display apparatus 100 according to one aspect of the present disclosure may be provided such that color filters having different colors partially overlap each other at a boundary portion of the plurality of subpixels SP. In this case, the display apparatus 100 according to one aspect of the present disclosure may prevent the light emitted from each subpixel SP from being emitted to the adjacent subpixel SP due to the color filters overlapped with each other at the boundary portion of the subpixels SP, thereby preventing color mixture between the subpixels SP from occurring.

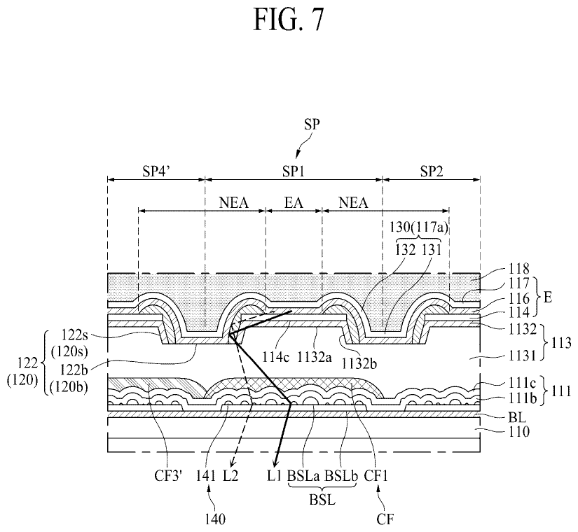

Referring to FIG. 6, the pixel electrode 114 of the subpixel SP may be formed on the overcoat layer 113. The pixel electrode 114 may be connected to a drain electrode or a source electrode of the thin film transistor 112 through a contact hole passing through the overcoat layer 113 and the passivation layer 111c. In FIG. 6, the pixel electrode 114 may be provided to be wider than the second layer 1132. However, the pixel electrode 114 may be provided to be narrower than the second layer 1132 in accordance with the cross-section position or other aspects. For example, as shown in FIG. 7, the pixel electrode 114 may be provided to be narrower than the second layer 1132. As shown in FIG. 6, when the pixel electrode 114 is provided to be wider than the second layer 1132, an edge portion of the pixel electrode 114 may be connected to the drain electrode or the source electrode in the circuit area CA. In this case, the edge portion of the pixel electrode 114 may be covered by the bank 115. The pixel electrode 114 may be made of at least one of a transparent metal material or a semi-transmissive metal material.

Because the display apparatus 100 according to an aspect of the present disclosure is configured as the bottom emission type, the pixel electrode 114 may be formed of a transparent conductive material (or TCO), such as indium tin oxide (ITO) and indium zinc oxide (IZO) capable of transmitting light, or a semi-transmissive conductive material such as magnesium (Mg), silver (Ag), and an alloy of Mg and Ag.

Meanwhile, the material constituting the pixel electrode 114 may include MoTi. The pixel electrode 114 may be a first electrode or an anode electrode.

Referring to FIG. 3, in the display apparatus 100 according to one aspect of the present disclosure, the pixel electrode 114 may be formed to cover the upper surface 1132a and the side surfaces 1132b of the second layer 1132. That is, the pixel electrode 114 may be disposed to be extended from the upper surface of the overcoat layer 113 (or the second layer 1132) to the side surfaces of the overcoat layer 113. In this case, an end (or an end portion) of the pixel electrode 114 may contact the first layer 1131. As the pixel electrode 114 is formed to cover the upper surface 1132a and the side surfaces 1132b of the second layer 1132, the nano-lens portion 140 including the plurality of the nano-lenses 141 may be disposed on the upper surface 1132a and the side surfaces 1132b of the second layer 1132.

Referring to FIG. 4, at least one of the side surfaces 1132b of the overcoat layer 113 may be disposed to face the reflective portion 130 (or the curved surface 132 of the reflective portion 130). Therefore, the plurality of the nano-lenses 141 on the side surfaces 114b of the pixel electrode 114 disposed on the side surfaces 1132b of the overcoat layer 113 may be disposed to face to the reflective portion 130 (or the curved surface 132 of the reflective portion 130). As a result, in the display apparatus 100 according to one aspect of the present disclosure, the reflective portion 130 and some of the plurality of the nano-lenses 141 are disposed to face each other, thus the plurality of the nano-lenses 141 may scatter (or reflect and/or refract) the light reflected by the reflective portion 130, thereby maximizing the efficiency of the light extraction and/or characteristic of the viewing angle.

After forming the pixel electrode 114, by proceeding the plasma process using Hydrogen (H) or Ammonia (NH₃), the plurality of the nano-lenses 141 may be randomly and unevenly formed on the upper surface 114a and the side surfaces 114b of the pixel electrode 114. As mentioned above, since the plasma process using Hydrogen (H) or Ammonia (NH₃) is performed on the pixel electrode 114 including ITO, each of the plurality of the nano-lenses 141 may be formed to include more indium (In) than the pixel electrode 114. Accordingly, the plurality of the nano-lenses 141 may have a light reflectance greater than the light reflectance of the pixel electrode 114 including a transparent conductive material.

Since the unevenly formed nano-lenses 141 are disposed on the upper surface 114a and the side surfaces 114b of the pixel electrode 114, the optical path of light directed toward the nano-lens 141 among light emitted from the light emitting layer 116 may be changed by the nano-lens 141. That is, scattering may occur due to the nano-lens 141. Therefore, the display apparatus 100 according to one aspect of the present disclosure may reduce a total reflectance at the interface between the substrate 110 and the air layer due to a scattering effect by the plurality of the nano-lenses 141, and thus the light extraction efficiency (or a luminous efficiency) may be further improved compared to a display apparatus that does not have the plurality of nano-lenses 141.

Meanwhile, in the display apparatus 100 according to one aspect of the present disclosure, the lower surface 114c of the pixel electrode 114 may be flat. In the case of display apparatus in which the lower surface of the pixel electrode has lens shapes or uneven shapes, there is a problem that external light is reflected twice on the lower surface of the pixel electrode, resulting in a diffraction pattern of the reflected light. Consequently, in the display apparatus 100 according to one aspect of the present disclosure, since the lower surface 114c of the pixel electrode 114 may be flat, diffraction patterns of the reflected light may be reduced or minimized compared to the case that the lower surface of the pixel electrode has lens shape or uneven shape. The reflected light may refer to the light that is incident from the outside of the substrate 110, is reflected on the lower surface of a transparent conductive material (or transparent metal layer) such as pixel electrode 114, and is emitted to the outside of the substrate 110. As a result, in the display apparatus 100 according to one aspect of the present disclosure, since the lower surface 114c of the pixel electrode 114 may be flat, the occurrence of radial rainbow patterns and radial circular ring patterns of the reflected light may be reduced or minimized due to the unevenness or randomness of diffraction patterns of the reflected light. Therefore, the display apparatus 100 according to one aspect of the present disclosure may reduce diffraction patterns and/or external light reflectance using a general polarizer without a special polarizer preventing diffraction patterns, thereby reducing manufacturing costs.

A bank 115 is an area in which light is not emitted and may be provided to surround each light emitting portion included in each of the plurality of the subpixels SP. That is, the bank 115 may partition (or define) the light emission area EA included in each of the light emitting portions or each of the subpixels SP. The light emitting portion may refer to a portion of the light emitting layer 116 where the pixel electrode 114 is in contact with the lower surface and the reflective electrode 117 is in contact with the upper surface.

The bank 115 may be formed to cover the edge of each pixel electrode 114 of each of the subpixels SP and expose a portion of each of the pixel electrodes 114. That is, the bank 115 may partially cover the pixel electrode 114. Therefore, the bank 115 may prevent the pixel electrode 114 and the reflective electrode 117 from being in contact with each other at the end of each pixel electrode 114.

Meanwhile, since the bank 115 covers an edge of the pixel electrode 114, a portion of the plurality of the nano-lenses 141 formed on the pixel electrode 114 may be also covered by the bank 115. An exposed portion of the pixel electrode 114 that is not covered by the bank 115 may be included in the light emitting portion. The light emitting portion, as shown in FIG. 4, may be formed on the plurality of the nano-lenses 141, thus the light emitting portion (or the light emission area EA) may overlap some of the plurality of the nano-lenses 141 in a direction of the thickness of the substrate 110.

After the bank 115 is formed, the light emitting layer 116 may be formed to cover the pixel electrode 114, the plurality of the nano-lenses 141, and the bank 115. Accordingly, the bank 115 is provided between the pixel electrode 114 (or the nano-lens 141) and the light emitting layer 116. The bank 115 may be expressed in terms of a pixel defining layer. The bank 115 according to one exemplary aspect may include organic materials. In case that the bank 115 includes organic materials, the bank 115 in the non-light emission (or non-emission) area NEA may have different thicknesses depending on their location. In addition, when the bank 115 is made of an organic material, since the upper surface of the bank 115 may be provided to be flat, the light emitting layer 116, the reflective electrode 117 and the encapsulation layer 118, which are formed on the upper surface of the bank 115 in a subsequent process, may be provided to be also flat, but the present disclosure is not limited thereto. The bank 115 may be made of an inorganic material. When the bank 115 is made of an inorganic material, the bank 115 may be formed to have the same or similar thickness along the profile of the pattern portion 120 (or the second layer 1132).

Referring further to FIG. 4, the light emitting layer 116 may be formed on the pixel electrode 114, the plurality of the nano-lenses 141, and the bank 115. The light emitting layer 116 may be provided between the pixel electrode 114 (or the plurality of the nano-lenses 141) and the reflective electrode 117. Thus, when a voltage is applied to each of the pixel electrode 114 and the reflective electrode 117, an electric field is formed between the pixel electrode 114 and the reflective electrode 117. Therefore, the light emitting layer 116 may emit light. The light emitting layer 116 may be formed of a plurality of subpixels SP and a common layer provided on the bank 115.

The light emitting layer 116 according to an aspect may be provided to emit white light. The light emitting layer 116 may include a plurality of stacks which emit lights of different colors. For example, the light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and the plurality of the nano-lenses 141 and may be implemented a structure where a hole injection layer (HIL), a hole transport layer (HTL), an emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to an aspect of the present disclosure, because the light emitting layer 116 is provided as a common layer, the first stack, the charge generating layer, and the second stack may be arranged all over the plurality of subpixels SP.

According to another aspect, the light emitting layer 116 may be provided to emit lights of different colors and may be patterned in each of the plurality of subpixels SP. However, in this case, a hole injection layer (HIL), a hole transport layer (HTL), an emission transport layer (ETL), and an electron injection layer (EIL) except the light emitting layer may be arranged as a common layer in the subpixels SP. Also, in a case where the light emitting layer 116 is patterned in each of the subpixels SP, a color filter may not be provided between the substrate 110 and the light emitting layer 116.

The reflective electrode 117 may be formed on the light emitting layer 116. The reflective electrode 117 according to one example may include a metal material. The reflective electrode 117 may reflect the light emitted from the light emitting layer 116 in the plurality of subpixels SP toward the lower surface of the substrate 110. Therefore, the display apparatus 100 according to one aspect of the present disclosure may be implemented as a bottom emission type display apparatus.

The display apparatus 100 according to one aspect of the present disclosure is a bottom emission type and has to reflect light emitted from the light emitting layer 116 toward the substrate 110, and thus the reflective electrode 117 may be made of a metal material having high reflectance. The reflective electrode 117 according to one example may be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The reflective electrode 117 may be expressed as terms such as a second electrode, a cathode electrode and a counter electrode.

Meanwhile, in the display apparatus 100 according to one aspect of the present disclosure, the reflective portion 130 may be a portion of the reflective electrode 117. Therefore, the reflective portion 130 may reflect light, which is directed toward the adjacent subpixel SP, toward the light emission area EA of the subpixel SP for emitting light. Since the reflective portion 130 is a portion of the reflection electrode 117, as shown in FIG. 3, the reflective portion 130 may be denoted by a reference numeral 117a. In the present disclosure, the reflective portion 130 may mean the reflective electrode 117 that overlaps the pattern portion 120. In particular, the reflective portion 130 may mean the reflective electrode 117 (or the curved surface 132 of the reflective portion 130) that is inclined while being overlapped with the pattern portion 120. Therefore, as shown in FIG. 3, the reflective portion 130 may reflect light that is directed toward the adjacent subpixel SP, or light that is dissipated through total reflection between interfaces, toward the light emission area EA of the subpixel SP for emitting light.

The encapsulation layer 118 is formed on the reflective electrode 117. The encapsulation layer 118 serves to prevent oxygen or moisture from being permeated into the light emitting layer 116 and the reflective electrode 117. To this end, the encapsulation layer 118 may include at least one inorganic film and at least one organic film.

Meanwhile, as shown in FIG. 3, the encapsulation layer 118 may be disposed not only in the light emission area EA but also in the non-light emission (or non-emission) area NEA. The encapsulation layer 118 may be disposed between the reflective electrode 117 and an opposing substrate 200.

Hereinafter, the pattern portion 120, the reflective portion 130, and the nano-lens portion 140 of the display apparatus 100 according to one aspect of the present disclosure will be described in more detail with reference to FIGS. 1 to 6.

In the display apparatus 100 according to one aspect of the present disclosure, the pattern portion 120 may be provided near the light emission area EA (or near the non-light emission (or non-emission) area NEA) and the reflective portion 130 may be provided on the pattern portion 120 to prevent light extraction efficiency from being reduced as some of the light emitted from the light emitting element layer is not discharged to the outside due to total reflection on an interface between the light emitting element layer and the electrode and/or an interface between the substrate and the air layer. Also, the plurality of the nano-lenses 141 are provided on the pixel electrode 114, thus the light emitted from the light emitting layer 116 may be scattered.

For example, as shown in FIG. 3, the pattern portion 120 may be formed to be concave in the first layer 1131 of the overcoat layer 113. As shown in FIGS. 2 and 3, the pattern portion 120 may be disposed near the non-light emission (or non-emission) area NEA. That is, the pattern portion 120 may be disposed to surround the light emission area EA. The pattern portion 120 may be formed by patterning and removing boundaries of the first layer 1131 between the subpixels SP after the first layer 1131 is formed. The pattern portion 120 according to one aspect may be disposed to surround the light emission area EA in the form of a slit or a trench. The pattern portion 120 may include a bottom surface 120b and an inclined surface 120s.

The bottom surface 120b of the pattern portion 120 according to one exemplary aspect is a surface formed closest to the substrate 110 in the pattern portion 120 and may be disposed closer to the substrate 110 (or an upper surface of the substrate 110) than the pixel electrode 114 (or the upper surface 114a of the pixel electrode 114) in the light emission area EA. Meanwhile, since the shallower the depth of the pattern portion 120, the smaller the area of the reflective portion 130 disposed on the pattern portion 120, the light extraction efficiency may be decreased. Therefore, in the display apparatus 100 according to one aspect of the present disclosure, the depth of the pattern portion 120 may be set up in a range of not decreasing the light extraction efficiency by the reflective portion 130 disposed on the pattern portion 120.

The inclined surface 120s of the pattern portion 120 may be disposed to be inclined between the bottom surface 120b and the light emission area EA. Thus, the inclined surface 120s of the pattern portion 120 may be provided to surround the light emission area EA. As shown in FIG. 3, the inclined surface 120s may be connected to the bottom surface 120b. The inclined surface 120s may be formed to have a predetermined angle with the bottom surface 120b. For example, the predetermined angle between the inclined surface 120s and the bottom surface 120b may be an obtuse angle. Therefore, a width of the pattern portion 120 may be gradually reduced toward a direction (or the third direction, e.g., Z-axis direction) from the opposing substrate 200 (or the reflective portion 130) toward the substrate 110. As the obtuse angle is formed by the inclined surface 120s and the bottom surface 120b, the light emitting element layer E (or the light emitting element layer E including the reflective portion 130) including the second layer 1132, the bank 115, pixel electrode 114 and the reflective portion 130, which are formed in a subsequent process, may be formed to be concave along the profile of the pattern portion 120. Therefore, the light emitting element layer E (or the reflective portion 130) may be formed to be concave on the pattern portion 120 formed to be concave in the non-light emission (or non-emission) area NEA (or the peripheral area). The light emitting element layer E (or the reflective portion 130) formed to be concave in the pattern portion 120 may mean that it includes at least one of the pixel electrode 114, the light emitting layer 116 and the reflective electrode 117.

As shown in FIG. 2, the pattern portion 120 may be provided to surround the light emission area EA. As the pattern portion 120 is provided to surround the light emission area EA, at least a portion of the reflective portion 130 disposed on the pattern portion 120 may be provided to surround the light emission area EA. Therefore, in the display apparatus 100 according to one aspect of the present disclosure, since light may be extracted even from the non-light emission (or non-emission) area NEA near the light emission area EA through the reflector 130, overall light efficiency may be improved. Therefore, the display apparatus 100 according to one aspect of the present disclosure may have the same light emission efficiency or more improved light emission efficiency even with low power as compared with a general display apparatus having no pattern portion 120 and reflective portion 130 on the pattern portion 120, whereby overall power consumption may be reduced.

In addition, the display apparatus 100 according to one aspect of the present disclosure may allow the light emitting element layer E to emit light even with low power, thereby improving lifespan of the light emitting element layer E.

Referring back to FIG. 2, the pattern portion 120 may include a first pattern line 121 disposed in the first direction (e.g., X-axis direction) between the circuit area CA and the light emission area EA and a second pattern line 122 disposed in the second direction (e.g., Y-axis direction) crossing the first direction (X-axis direction). Referring to FIG. 2, the first pattern line 121 may mean the pattern portion 120 disposed in a horizontal direction, and the second pattern line 122 may mean the pattern portion 120 disposed in a vertical direction.

The first pattern line 121 may include a bottom surface 121b and an inclined surface 121s (shown in FIG. 6). The second pattern line 122 may include a bottom surface 122b (shown in FIG. 4) and an inclined surface 122s (shown in FIG. 4). Since each of the bottom surface 121b and the inclined surface 121s of the first pattern line 121 and each of the bottom surface 122b and the inclined surface 122s of the second pattern line 122 are the same as each of the bottom surface 120b and the inclined surface 120s of the pattern portion 120, their description will be replaced with the description of the bottom surface 120b and the inclined surface 120s of the pattern portion 120. The first pattern line 121 and the second pattern line 122 may be connected to one in the non-light emission (or non-emission) area NEA (or the peripheral area) to surround the light emission area EA. However, as shown in FIG. 2, a first pattern line 121 may be disconnected in a portion connecting the light emission area EA and a circuit area CA.

The first pattern line 121 may be disposed between the subpixels SP for emitting light of the same color. For example, the first pattern line 121 may be disposed between the first subpixels SP1 disposed in the second direction (Y-axis direction). Therefore, the first pattern line 121 may be disposed in the first direction (X-axis direction). In contrast, the second pattern line 122 may be disposed between the subpixels SP for emitting light of different colors. For example, the second pattern line 122 may be disposed between the first subpixel SP1 that is a red subpixel, and the second subpixel SP2 that is a green pixel. Therefore, the second pattern line 122 may be disposed in the second direction (Y-axis direction).

Since the second pattern line 122 is disposed between the subpixels SP for emitting light of different colors, the reflective portion 130 on the second pattern line 122 may prevent light of different colors from being emitted to other adjacent subpixels SP. Therefore, the display apparatus 100 according to the present disclosure may prevent color mixture (or color distortion) between the subpixels SP for emitting light of different colors, thereby improving color purity.

The second layer 1132 of the overcoat layer 113 may be further extended from the light emission area EA to the non-light emission (or non-emission) area NEA to partially cover the inclined surface 120s of the pattern portion 120. Therefore, as shown in FIG. 3, an end 1132c of the second layer 1132 may be in contact with the bottom surface 120b of the pattern portion 120. In this case, the end 1132c of the second layer 1132 may be in contact with only a portion of the bottom surface 120b. When the second layer 1132 entirely covers the bottom surface 120b, the depth of the reflective portion 130 formed on the pattern portion 120 may be relatively lowered, thereby reducing reflective efficiency. Therefore, in the display apparatus 100 according to one aspect of the present disclosure, the second layer 1132 is provided to be in contact with only a portion of the bottom surface 120b without entirely covering the bottom surface 120b of the pattern portion 120 and thus the reflective portion 130 formed in a subsequent process may be formed to be close to the bottom surface 120b, whereby reflective efficiency may be improved.

The bank 115 may be extended to cover the side surface 1132b of the second layer 1132 covering the inclined surface 120s of the pattern portion 120 while covering the edge of the pixel electrode 114. Therefore, the bank 115 may be in contact with a portion of the bottom surface 120b of the pattern portion 120, which is not covered by the second layer 1132. When the bank 115 entirely covers the bottom surface 120b, the depth of the reflective portion 130 formed on the pattern portion 120 is lowered, whereby reflective efficiency may be reduced. Therefore, as shown in FIG. 3, each of the second layer 1132 and the bank 115 on the bottom surface 120b of the pattern portion 120 may be discontinuously provided. That is, each of the second layer 1132 and the bank 115 may be disconnected on the bottom surface 120b of the pattern portion 120. As a result, in the display apparatus 100 according to one aspect of the present disclosure, the bank 115 is provided to be in contact with only a portion of the bottom surface 120b without entirely covering the bottom surface 120b, so that the reflective portion 130 formed in a subsequent process may be formed to be close to the bottom surface 120b, whereby reflective efficiency may be improved. Likewise, the pixel electrode 114 may cover the upper surface 1132a and the side surfaces 1132b of the second layer 1132 and have an end partially contacting the bottom surface 120b of the pattern portion 120. Therefore, the pixel electrode 114 included in each of the subpixels SPs may be disconnected and not connected to each other.

Meanwhile, as shown in FIG. 3, since the second pattern line 122 is disposed between the subpixels SP for emitting light of different colors, the second layer 1132, the pixel electrode 114, the bank 115, the light emitting layer 116 and the reflective portion 130 may be provided to be symmetrical based on the center of the pattern portion 120 (or the second pattern line 122).

The first pattern line 121 may be disposed between the subpixels SP for emitting light of the same color. Therefore, as shown in FIG. 6, the second layer 1132 may be formed only to a portion adjacent to the light emission area EA, and the second layer 1132 may not be formed on an opposite side of the light emission area EA based on the first pattern line 121. As a result, since the first pattern line 121 is disposed between the subpixels SP for emitting light of the same color, the bank 115, the light emitting layer 116 and the reflective portion 130 may be provided to be asymmetrical based on the center of the pattern portion 120 (or the first pattern line 121) as shown on the left side of FIG. 6.

Referring to FIG. 6, the plurality of the nano-lenses 141 included in the nano-lens portion 140 may be formed through the plasma process after the pixel electrode 114 is formed. As a result, the display apparatus 100 according to one aspect of the present disclosure may have a structural feature in which the plurality of the nano-lenses 141 is disposed on the pixel electrode 114 that is connected to the drain electrode 112d of the thin film transistor.

Referring back to FIG. 4, in the display apparatus 100 according to one aspect of the present disclosure, the size of the nano-lens portion 140 may be equal to or larger than the size of the light emission area EA. The nano-lens portion 140 according to one exemplary aspect may have a second width W2 greater than a first width W1 of the light emission area EA. Thus, the nano-lens portion 140 may partially overlap the light emission area EA. Since the nano-lens portion 140 partially overlaps the light emission area EA, the light emitted from the light emitting layer 116, which mainly emits light, may be scattered by the plurality of the nano-lenses 141, so that the light totally reflected at the interface between the substrate 110 and the air layer may be reduced. Therefore, the display apparatus 100 according to one aspect of the present disclosure may improve the light extraction efficiency, thereby improving overall light emitting efficiency (or the luminance).

In addition, the display apparatus 100 according to one aspect of the present disclosure may further improve characteristic of the viewing angle due to a scattering effect by the plurality of nano-lenses 141, compared to a display apparatus that does not have the plurality of nano-lenses.

FIG. 7 is a schematic cross-sectional view of a display apparatus according to the second aspect of the present disclosure.

Referring to FIG. 7, the display apparatus 100 according to the second aspect of the present disclosure is the same as the display apparatus mentioned above according to FIGS. 1 to 6 except that the structure of the pixel electrode 114 is changed and the nano-lens portion 140 is disposed on a base layer BSL disposed on the same layer as the active layer 112a. Accordingly, the same reference numbers will be given to the same configuration, hereinafter only the different configurations will be described below.

In the case of the display apparatus according to FIG. 4 described above, the nano-lens portion 140 is disposed on the upper surface 114a and the side surfaces 114b of the pixel electrode 114. Thus, in the case of the display apparatus according to FIG. 4, the plurality of the nano-lenses 141 may be disposed on the upper surface 114a and the side surfaces 114b of the pixel electrode 114. Therefore, in the display apparatus according to FIG. 4, a portion of light emitted from the light emitting layer 116 may be emitted to the outside through the lower surface of the substrate 110 after the optical path of the light is changed on the upper side of the overcoat layer 113.

On the other hand, the display apparatus 100 according to FIG. 7 further may include the base layer BSL disposed between the passivation layer 111c and the substrate 110, the nano-lens portion 140 may be disposed on an upper surface BSLa of the base layer BSL facing the lower surface 114c of the pixel electrode 114. Accordingly, as shown in FIG. 7, a portion of light emitted from the light emitting layer 116 may be emitted to the outside through the lower surface of the substrate 110 after being firstly reflected by the reflective portion 130 and secondly reflected by the nano-lens portion 140 disposed on the upper surface BLSa of the base layer BSL. That is, in the display apparatus 100 according to FIG. 7, light may be emitted to the outside after the optical path of the light is changed below the overcoat layer 113.

Meanwhile, in the display apparatus 100 according to FIG. 7, since the optical path of light may be changed on the nano-lens portion 140 disposed between the overcoat layer 113 and the substrate 110, the pixel electrode 114 may be not formed on the side surfaces 1132b of the overcoat layer 113. The pixel electrode 114 is formed only on the upper surface 1132a of the overcoat layer 113, not on the side surfaces 1132b of the overcoat layer 113, thus the width of the light emission area EA may be widened as much as the width of the area in which the pixel electrode is not formed on the side surfaces 1132b of the overcoat 113, thereby improving the light emitting efficiency.

In the display apparatus according to the second aspect of the present disclosure, the base layer BSL may include IGZO which is a transparent conductive material. After the base layer BSL including IGZO is formed, the plasma process using Hydrogen (H) or Ammonia (NH 3) is performed, thus the plurality of the nano-lenses 141 may be formed by precipitation of Indium (In) by radical reaction of Oxygen (O) and Hydrogen (H) in IGZO according to the following formula.

3H₂+In₂O₃→3H₂O+2In

According to the chemical formula as described above, by the plasma process, Oxygen (O) contained in the base layer BSL which is a transparent conductive material, may be combined with Hydrogen (H), which is the plasma gas, to generate water (H₂O), thereby being precipitated Indium (In). Therefore, the plurality of the nano-lenses 141 (or the nano-lens portion 140) may include more Indium (In) than the base layer BSL. Therefore, the plurality of the nano-lenses 141 are closer to a metal than the base layer BSL, the light reflectance may be higher than the base layer BSL. Accordingly, as shown in FIG. 7, light emitted from the light emitting layer 116 and reflected by the reflective portion 130 may be reflected by the nano-lens 141 including more Indium (In) than the base layer BSL, so that its optical path may be changed to be emitted as the first extraction light L1 and/or the second extraction light L2.

As described above, since the plurality of the nano-lenses 141 are randomly and unevenly formed on the upper surface BSLa of the base layer BSL by the plasma process using Hydrogen (H) or Ammonia (NH₃), the plurality of the nano-lenses 141 may have different sizes, shapes, and intervals. Therefore, the amount of Indium (In) included in the plurality of the nano-lenses 141 may be different, thus some of the plurality of the nano-lenses 141 may include Indium(In) similar to the base layer BSL or slightly more than the base layer BSL. In this case, the nano-lens 141 may have characteristic similar to the base layer BSL, thus the nano-lens 141 may transmit a portion of the light and reflect another portion of the light.

Meanwhile, some of the plurality of the nano-lenses 141 may have characteristic similar to the base layer BSL, however, the amount of the Indium thereof may be different, therefore the base layer BSL and the nano-lens 141 may have different refractive indices. Therefore, the light transmitting some of the nano-lenses 141 among the plurality of the nano-lenses 141 may be refracted by the interface between the nano-lens 141 and the base layer BSL, thus its optical path may be changed.

Accordingly, the light reflected by the reflective portion 130 to be directed toward the nano-lens portion 140 among the light emitted from the light emitting layer 116, may be reflected and/or refracted by the nano-lens portion 140 disposed on the upper surface BSLa of the base layer BSL to emit to the outside of the substrate 110. As described above, the optical path of the light emitted from the light emitting layer 116 may be changed by the reflective portion 130 and the nano-lens portion 140 spaced apart from the reflective portion 130.

Consequently, in the display apparatus according to the second aspect of the present disclosure, the optical path in each of the subpixels SP is changed by the nano-lens portion 140 spaced apart from the reflective portion 130, so that the total reflection in the interface between the substrate 110 and the air layer may be reduced, and the light extraction efficiency of light emitted from the light emitting layer 116 may be improved.

Referring back to FIG. 7, the base layer BSL may be provided to be flat and partially overlap the light emission area EA. For example, the base layer BSL is formed to have a width greater than a width of the pixel electrode 114, and is disposed to have a center portion of the base layer BSL overlap a center portion of the pixel electrode 114, so that the base layer BSL may partially overlap the light emission area EA. Since the base layer BSL is provided to have a width equal to or smaller than a width of the subpixel SP, color mixing with adjacent subpixels SP may be prevented.

In the display apparatus 100 according to the second aspect of the present disclosure, the base layer BSL may be disposed on the same layer as the active layer 112a. In addition, the base layer BSL may be provided to include IGZO which is the same material as the active layer 112a. This is because, the base layer BSL and the active layer 112a are formed on the same layer through the same process, in only a different position on the plane. For example, the base layer BSL may be disposed between the buffer layer BL and the interlayer insulating layer 111b. In addition, the active layer 112a may be disposed in the circuit area CA, on the other hand, the base layer BSL may be disposed to partially overlap the light emission area EA.

Meanwhile, after forming the base layer BSL, the plasma process, which forms the nano-lens portion 140, is performed, as described above, the active layer 112a is disposed on the same layer as the base layer BSL, thus the active layer 112a may be damaged by the plasma process. Therefore, in the display apparatus 100 according to the second aspect of the present disclosure, before the plasma process is performed, the photoresist PR is formed on a remaining area (for example, on the active layer 112a) except the base layer BSL, thereafter, the plasma process using Hydrogen (H) or Ammonia (NH₃) may be performed. The photoresist PR may be removed after the nano-lens portion 140 is formed on the base layer BSL through the plasma process. As a result, in the display apparatus 100 according to the second aspect of the present disclosure, the plurality of the nano-lenses 141 having lens shapes or uneven shapes may be formed on the base layer BSL without damaging the active layer 112a by the plasma process.

Referring to FIG. 7, in the display apparatus 100 according to the second aspect of the present disclosure, the lower surface BSLb of the base layer BSL is provided to be flat. Consequently, in the display apparatus 100 according to the second aspect of the present disclosure, diffraction patterns of the reflected light may be reduced or minimized compared to the case where the lower surface of the base layer or the lower surface of the pixel electrode have convex lens shapes or convex uneven shape. The reflected light may refer to the light that is incident from the outside of the substrate 110, is reflected on the lower surface of a transparent conductive material (or transparent metal layer) such as pixel electrode 114 or base layer BSL, and is emitted to the outside of the substrate 110. As a result, in the display apparatus 100 according to the second aspect of the present disclosure, since the lower surface BLSb of the base layer BLS may be flat, the occurrence of radial rainbow patterns and radial circular ring patterns of the reflected light may be reduced or minimized due to the unevenness or randomness of diffraction patterns of the reflected light. Therefore, the display apparatus 100 according to the second aspect of the present disclosure may reduce diffraction patterns and/or external light reflectance using a general polarizer without a special polarizer preventing diffraction patterns, thereby reducing manufacturing costs.

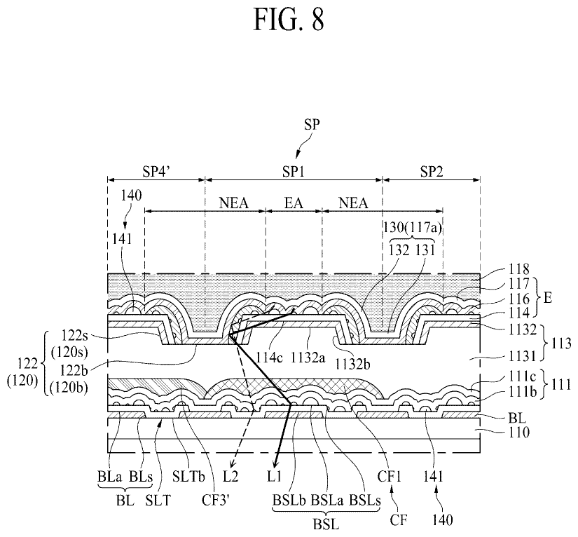

FIG. 8 is a schematic cross-sectional view of a display apparatus according to the third aspect of the present disclosure.

Referring to FIG. 8, the display apparatus 100 according to the third aspect of the present disclosure is the same as the display apparatus mentioned above according to FIGS. 1 to 6, except that the nano-lens portion 140 is also disposed on the base layer BSL disposed on the same layer as the active layer 112a, and the buffer layer BL is patterned. Accordingly, the same reference numbers will be given to the same configuration, only the different configurations will be described below.

In the case of the display apparatus according to FIG. 4 described above, the nano-lens portion 140 is disposed on the upper surface 114a and the side surfaces 114b of the pixel electrode 114. Thus, in the case of the display apparatus according to FIG. 4, the plurality of the nano-lenses 141 may be disposed on the upper surface 114a and the side surfaces 114b of the pixel electrode 114. Therefore, in the display apparatus according to FIG. 4, a portion of the light emitted from the light emitting layer 116 may be emitted to the outside through the lower surface of the substrate 110 after the optical path of the light is changed on the upper side of the overcoat layer 113.

On the other hand, the display apparatus 100 according to FIG. 8 further includes the base layer BSL disposed between the buffer layer BL and the passivation layer 111c and between the substrate 110 and the passivation layer 111c, and the nano-lens portion 140 may be also disposed on the upper surface BSLa and the side surfaces BSLs of the base layer BSL. The upper surface BSLa of the base layer BSL is facing the lower surface of the passivation layer 111c. Accordingly, as shown in FIG. 8, after a portion of the light emitted from the light emitting layer 116 may be firstly reflected by the nano-lens portion 140 disposed on the pixel electrode 114, and may be secondly reflected by the reflective portion 130. The light secondly reflected by the reflective portion 130 may be thirdly reflected by the nano-lens portion 140 disposed on the upper surface BSLa of the base layer BSL, thereafter the thirdly reflected light may be emitted outside through the lower surface of the substrate 110. That is, the display apparatus 100 according to FIG. 8, a portion of the light emitted from the light emitting layer 116 may emit light to the outside after the optical path of the light is changed over the overcoat layer 113 and below the overcoat layer 113, respectively.

Meanwhile, in the display apparatus 100 according to FIG. 8, the base layer BSL may partially overlap the pixel electrode 114. For example, the base layer BSL may have a width greater than the width of the pixel electrode 114 and may be disposed such that the center portion of the base layer BSL the center portion of the pixel electrode 114 overlap. Accordingly, the base layer BSL may partially overlap the pixel electrode 114 and/or the light emission area EA. Thus, in the display apparatus 100 according to FIG. 8, the nano-lens portion 140 disposed on the base layer BSL and the nano-lens portion 140 disposed on the pixel electrode 114 may be doubly overlapped in the direction of thickness of the substrate 110. Therefore, the display apparatus 100 according to FIG. 8 may maximize the efficiency of the light extraction and characteristic of the viewing angle because a scattering effect may be further improved through the nano-lens portion 140 having the double-overlapping structure. Meanwhile, since the width of the base layer BSL is smaller than or equal to the width of the subpixel SP, color mixing with adjacent subpixels SP may be prevented.

In the display apparatus 100 according to the third aspect of the present disclosure, the base layer BSL may include IGZO, which is a transparent conductive material. After the base layer BSL including IGZO is formed, the plasma process using Hydrogen (H) or Ammonia (NH 3) is performed, thus the plurality of the nano-lenses 141 may be formed by precipitation of Indium (In) by radical reaction of Oxygen (O) and Hydrogen (H) in IGZO according to the following formula.

3H₂+In₂O₃→3H₂O+2In

According to the chemical formula as described above, by the plasma process, Oxygen (O) contained in the base layer BSL which is a transparent conductive material, may be combined with Hydrogen (H), which is the plasma gas, to generate water (H₂O), thereby being precipitated Indium (In). Therefore, the plurality of the nano-lenses 141 (or the nano-lens portion 140) may include more Indium (In) than the base layer BSL. Therefore, the plurality of the nano-lenses 141 are closer to a metal than the base layer BSL, the light reflectance may be higher than the base layer BSL. Accordingly, as shown in FIG. 8, light emitted from the light emitting layer 116 and reflected by the reflective portion 130 may be reflected by the nano-lens 141 including more Indium (In) than the base layer BSL, so that its optical path may be changed to be emitted as the first extraction light L1 and/or the second extraction light L2.

Meanwhile, in the display apparatus according to the third aspect of the present disclosure, each of the plurality of the subpixels SP may include a slit portion SLT, provided by partially removing the buffer layer BL. In this case, the buffer layer BL may include side surfaces BLs of the buffer layer BL, which is adjacent to the silt portion SLT and connected to the upper surface BLa of the buffer layer BL. The slit portion SLT may include a lower surface SLTb adjacent to the upper surface of the substrate 110. As shown in FIG. 8, as the slit portion SLT is formed in the buffer layer BL, the base layer BSL may include a concave portion formed to be concave along a profile of the slit portion SLT and the side surfaces BLs of the buffer layer BL. Therefore, the base layer BSL may be in contact with the lower surface SLTb of the slit portion SLT, the side surfaces BLs of the buffer layer BL, and the upper surface BLa of the buffer layer BL.

Since the plurality of the nano-lenses 141 are randomly and unevenly formed on the upper surface BSLa and the side surfaces BSLs of the base layer BSL by the plasma process using Hydrogen (H) or Ammonia (NH₃), the plurality of the nano-lenses 141 may have different sizes, shapes, and intervals. Therefore, the amount of Indium(In) included in the plurality of the nano-lens 141 may be different from each other, and thus some of the plurality of the nano-lenses 141 may include Indium(In) similar to the base layer BSL or slightly more than the base layer BSL. In this case, the nano-lens 141 may have characteristic similar to the base layer BSL, thus the nano-lens 141 may transmit a portion of the light and reflect another portion of the light.

Meanwhile, some of the plurality of the nano-lenses 141 may have characteristic similar to the base layer BSL, however, the amount of the Indium thereof may be different, therefore the base layer BSL and the nano-lens 141 may have different refractive indices. Therefore, the light transmitting some of the nano-lenses 141 among the plurality of the nano-lenses 141 may be refracted on the interface between the nano-lens 141 and the base layer BSL, thus its optical path may be changed.

Accordingly, the light reflected by the reflective portion 130 and directed toward the nano-lens portion 140 (or, the light reflected by the nano-lens portion 140 disposed on the pixel electrode 114 and directed toward the nano-lens portion 140 which is disposed on the upper surface BSLa and the side surfaces BSLs of the base layer BSL) among light emitted from the light emitting layer 116 may be reflected and/or refracted by the nano-lens portion 140 disposed on the upper surface BSLa and the side surfaces BSLs of the base layer BSL to transmit to the outside of the substrate 110. As described above, the optical path of light emitted from the light emitting layer 116 may be changed by the reflective portion 130 and the nano-lens portion 140 (the nano-lens portion 140 disposed on the pixel electrode 114 and the nano-lens portion 140 disposed on the base layer BSL) spaced apart from the reflective portion 130.

As a result, in each of the plurality of the subpixels SP of the display apparatus 100 according to the third aspect of the present disclosure, the optical path of light may be changed by the nano-lens portion 140, which is disposed apart from the reflective portion 130 and has double-overlapping structure, so that the total reflection in the interface between the substrate 110 and the air layer may be reduced, thus the light extraction efficiency of light emitted from the light emitting layer 116 may be improved.

In the display apparatus 100 according to the third aspect of the present disclosure, the base layer BSL may be disposed on the same layer as the active layer 112a. In addition, the base layer BSL may include IGZO which is the same material as the active layer 112a. A detailed description of this is given in the description of the display apparatus 100 according to the second aspect of the present disclosure, thus it will be omitted,

Referring to FIG. 8, in the display apparatus 100 according to the third aspect of the present disclosure, the base layer BSL may be formed to be concave due to the slit portion SLT formed in the buffer layer BL. However, the lower surface BSLb of the base layer BSL may be provided not to have convex lens shapes or an uneven convex shape, to have a predetermined width, and to be flat. Consequently, in the display apparatus 100 according to the third aspect of the present disclosure, diffraction patterns of the reflected light may be reduced or minimized compared to the case that the lower surface of the pixel electrode or the lower surface of the base layer have convex lens shapes or an uneven convex shape. The reflected light may refer to the light that is incident from the outside of the substrate 110, is reflected on the lower surface of a transparent conductive material (or transparent metal layer) such as pixel electrode or base layer, and is emitted to the outside of the substrate 110. As a result, in the display apparatus 100 according to the third aspect of the present disclosure, since the lower surface BSLb of the base layer BSL has a predetermined width and is flat, the occurrence of radial rainbow patterns and radial circular ring patterns of the reflected light may be reduced or minimized due to the unevenness or randomness of diffraction patterns of the reflected light. Therefore, the display apparatus 100 according to the third aspect of the present disclosure may reduce diffraction patterns and/or lower external light reflectance using a general polarizer without a special polarizer preventing diffraction patterns, thereby reducing manufacturing costs.

In the display apparatus of the present disclosure, since each of the plurality of the subpixels includes the nano-lens portion spaced apart from the reflective portion, the reduce total reflection between the interface the substrate and the air layer may be reduced, thereby improving the extraction efficiency of light emitted from the light emitting layer.

Moreover, in the display apparatus of the present disclosure, since the light may be scattered through the nano-lens portion including the plurality of the nano-lenses compared to a display device without the nano-lens portion, thereby improving characteristic of the viewing angle.

Moreover, in the display apparatus of the present disclosure, since the reflective portion and the nano-lens portion is disposed adjacent to the non-emission area, it is possible to extract the light from the non-emission area, thereby improving the overall light extraction efficiency.

Moreover, in the display apparatus of the present disclosure, since the efficiency of the light extraction may be improved through the nano-lens portion and/or the reflective portion, it is possible to obtain the light emitting efficiency equal to or greater than that of a display apparatus without the nano-lens portion and/or the reflective portion, thereby reducing the overall power consumption.

Moreover, in the display apparatus of the present disclosure, since one surface of a transparent metal layer disposed on the side where the external light is incident is flat, the diffraction pattern of the reflected light by the transparent metal layer may be reduced or minimized, thereby reducing or minimizing the occurrence of radial rainbow patterns and radial circular ring patterns.

The effects to be obtained from the present disclosure are not limited to those mentioned above, and other effects not mentioned will be apparent to one of ordinary skill in the art from the description.

While aspects of the present disclosure are described in more detail with reference to the accompanying drawings, the present disclosure is not necessarily limited to these aspects but may be practiced in various modifications without departing from the technical ideas of the present disclosure. Thus, it is intended that the present disclosure covers the modifications and variations of the aspects provided they come within the scope of the appended claims and their equivalents.

What is claimed is:

1. A display apparatus comprising:
a substrate including a plurality of subpixels;
a pattern portion having a concave shape and disposed between adjacent subpixels of the plurality of the subpixels; and
a reflective portion disposed on the pattern portion,
wherein each of the plurality of the subpixels includes:
a light emitting layer disposed on the substrate; and
a nano-lens portion including a plurality of nano-lenses, and disposed between the light emitting layer and the substrate and spaced apart from the reflective portion.

2. The display apparatus of claim 1, wherein the plurality of the subpixels include a light emission area and a non-emission area adjacent to the light emission area, and
wherein the nano-lens portion overlaps the light emission area.

3. The display apparatus of claim 2, wherein a size of the nano-lens portion is equal to or greater that a size of the light emission area.

4. The display apparatus of claim 1, wherein each of the plurality of the subpixels further includes a pixel electrode disposed below the light emitting layer, and
wherein the nano-lens portion is disposed on an upper surface of the pixel electrode facing the light emitting layer and disposed on side surfaces of the pixel electrode connected to the upper surface of the pixel electrode.

5. The display apparatus of claim 4, wherein the plurality of the nano-lenses are unevenly formed on the upper surface of the pixel electrode and on the side surfaces of the pixel electrode.

6. The display apparatus of claim 4, wherein the pixel electrode includes ITO (Indium/Tin/Oxide), and
wherein the nano-lens portion includes more Indium (In) than the pixel electrode.

7. The display apparatus of claim 4, wherein each of the plurality of the subpixels further includes:
a passivation layer disposed between the substrate and the pixel electrode; and
an overcoat layer having an upper surface and side surfaces and disposed between the passivation layer and the pixel electrode,
wherein the pixel electrode is extended from the upper surface of the overcoat layer to side surfaces of the overcoat layer.

8. The display apparatus of claim 7, wherein at least one of the side surfaces of the overcoat layer is disposed to face the reflective portion.

9. The display apparatus of claim 7, wherein the pattern portion includes a bottom surface and a slope surface connected to the bottom surface, the slope surface having incline, and
wherein the overcoat layer includes:
a first layer disposed between the passivation layer and the pixel electrode; and
a second layer covering the first layer and having an end contacting a portion of the bottom surface of the pattern portion,
wherein the nano-lens portion is disposed on an upper surface of the second layer and on side surfaces of the second layer.

10. The display apparatus of claim 1, wherein each of the plurality of the subpixels includes:
a pixel electrode disposed below the light emitting layer;
a passivation layer disposed between the pixel electrode and the substrate; and
a base layer disposed between the passivation layer and the substrate,
wherein the nano-lens portion is disposed on an upper surface of the base layer facing a lower surface of the pixel electrode.

11. The display apparatus of claim 10, wherein the base layer includes IGZO (Indium/Gallium/Zinc/Oxide), and
wherein the nano-lens portion includes more Indium (In) than the base layer.

12. The display apparatus of claim 10, wherein each of the plurality of the subpixels includes a thin film transistor having an active layer, and
wherein the base layer and the active layer are disposed on a same layer.

13. The display apparatus of claim 10, wherein the plurality of the subpixels includes a light emission area and a non-emission area adjacent to the light emission area, and
wherein the base layer is flat and overlaps the light emission area.

14. The display apparatus of claim 7, wherein each of the plurality of the subpixels further includes:
a buffer layer disposed between the passivation layer and the substrate; and
a base layer disposed between the buffer layer and the passivation layer and disposed between the substrate and the passivation layer,
wherein the nano-lens portion is disposed on an upper surface of the base layer facing a lower surface of the passivation layer and disposed on side surfaces of the base layer connected to the upper surface of the base layer.

15. The display apparatus of claim 14, wherein the base layer overlaps the pixel electrode.

16. The display apparatus of claim 14, wherein each of the plurality of the subpixels includes a slit portion adjacent to side surfaces of the buffer layer, and the side surfaces are connected to an upper surface of the buffer layer,
wherein the slit portion includes a lower surface adjacent to an upper surface of the substrate, and
wherein the base layer contacts the lower surface of the slit portion, the side surfaces of the buffer layer, and the upper surface of the buffer layer.

17. The display apparatus of claim 14, wherein the pixel electrode includes ITO (Indium/Tin/Oxide), and
wherein the nano-lens portion comprises Indium(In) more than the pixel electrode.

18. The display apparatus of claim 14, wherein the base layer includes IGZO (Indium/Gallium/Zinc/Oxide), and
wherein the nano-lens portion includes Indium(In) more than the base layer.

19. The display apparatus of claim 1, wherein the reflective portion includes a reflective electrode disposed on the light emitting layer.

20. The display apparatus of claim 1, wherein the plurality of the subpixels include a light emission area and a non-emission area adjacent to the light emission area, and
wherein the pattern portion is disposed apart from the light emission area.

21. The display apparatus of claim 20, wherein a width of the pattern portion decreases in a direction from the reflective portion to the substrate.

22. The display apparatus of claim 21, further comprising a color filter disposed on the substrate and converting the color of light emitted from the light emitting layer.

23. A display apparatus comprising:
a plurality of subpixels including an emitting area and a non-emitting area surrounding the emitting area;
a pattern portion disposed in the non-emitting area and surrounding a plurality of subpixels;
a reflective portion disposed on the pattern portion and having a curved surface; and
at least one optical path changing portion disposed in the emitting area and the non-emitting area.

24. The display apparatus of claim 23, wherein the pattern portion has a bottom surface and an inclined surface extended from the bottom surface.

25. The display apparatus of claim 24, wherein the pattern portion includes:
a pixel electrode disposed along the inclined surface of the pattern portion;
a bank layer disposed on the pixel electrode; and
a light emitting layer disposed on the bank layer.

26. The display apparatus of claim 25, wherein the at least one optical path changing portion includes a plurality of nano-lenses disposed on the pixel electrode.

27. The display apparatus of claim 25, wherein the pixel electrode includes a first part and a second part extended from the first part, and
wherein the first and second parts of the pixel electrode have an upper surface and a lower surface, and the lower surface of the first part is flat and faces the substrate.

28. The display apparatus of claim 25, wherein the reflective portion includes a reflective electrode disposed on the light emitting layer.

29. The display apparatus of claim 23, wherein the at least one optical path changing portion has a width greater than a width of the emission area.

30. The display apparatus of claim 26, wherein the plurality of nano-lenses are disposed on an upper surface of the first and second parts of the pixel electrode.

31. The display apparatus of claim 23, wherein the pattern portion includes a first pattern line extended along a first direction and a second pattern line extended along a second direction.

32. The display apparatus of claim 31, wherein the first pattern line is disposed between adjacent subpixels for emitting light with a same color, and the second pattern line is disposed between adjacent subpixels for emitting light with different color light.

33. The display apparatus of claim 23, wherein the reflective portion and the at least one optical path changing portion are configured to change optical paths of light in the emitting area and the non-emitting area.
